(19) United States
(12) Patent Application Publication
(10) Pub. No.: US 2015/0129172 A1
(43) Pub. Date: May 14, 2015

(54) HEAT TRANSFER APPARATUS AND METHOD

(71) Applicant: Bradley University, Peoria, IL (US)

(72) Inventors: David Zietlow, Peoria, IL (US); Steven Gutschlag, Peoria, IL (US); Timothy Swingler, Peoria, IL (US)

(21) Appl. No.: 14/537,307

(22) Filed: Nov. 10, 2014

Related U.S. Application Data
(63) Continuation-in-part of application No. 13/851,801, filed on Mar. 27, 2013, now Pat. No. 8,893,738.
Application No. 13/851,801 is a continuation of application No. 12/022,673, filed on Jan. 30, 2008, now Pat. No. 8,424,551.
(60) Provisional application No. 60/898,337, filed on Jan. 30, 2007.

(51) Int. Cl. H05K 7/20; F28F 13/08; G06F 17/50; F28F 9/02

(52) U.S. Cl. CPC H05K 7/20281; F28F 9/0275; F28F 13/08; H05K 7/20272; H05K 7/20327; H05K 7/20263; G06F 17/5009
USPC 165/96; 165/174; 165/104.19; 165/104.21; 361/699; 703/6

(57) ABSTRACT

A heat transfer apparatus and related methods are provided. The heat transfer apparatus and related methods more precisely distribute fluid flow to meet heat removal needs in single-phase and/or a two-phase heat exchange systems by restricting fluid flow through one or more heat exchanger channels.

### CROSS-REFERENCE TO RELATED APPLICATIONS

This application is a continuation-in-part of, and claims priority to, co-pending U.S. patent application Ser. No. 13/851,801, filed Mar. 27, 2013, now U.S. Pat. No. 8,893,738, which claims priority to U.S. patent application Ser. No. 12/022,673, filed Jan. 30, 2008, now U.S. Pat. No. 8,424,551, which claims priority to U.S. Provisional Patent Application Ser. No. 60/898,337, filed Jan. 30, 2007, the entire disclosures of which are incorporated herein by reference.

### FIELD

The present invention relates generally to heat exchange systems. More specifically, the present invention is concerned with (1) methods to optimize flow in single-phase and/or two-phase heat exchange systems and (2) devices and methods that incorporate restricted flow manifolds using variable restrictions to provide predetermined fluid flow in single-phase and/or two-phase systems for better thermal management.

### BACKGROUND

### References

The following references are cited by number throughout this disclosure and provide general background information. Applicant makes no statement, inferred or direct, regarding the status of these references as prior art. Applicant reserves the right to challenge the veracity of statements made in these references, which are incorporated herein by reference.
1. Chisholm, D. (1983) Two-Phase Flow in Pipes and Heat Exchangers. George Godwin/Institution of Chemical Engineers, London. 1-24,106-113, 123-128.
2. Paliwoda, A. (1992) “Generalized Method of Pressure Drop Calculation Across Pipe Components Containing Two-Phase Flow of Refrigerants”. International Journal of Refrigeration. Vol 15, No. 2, p. 119-125.
3. Watanabe, M., Katsuta, M. and Nagata, K. (1995) Two-phase flow distribution in multi-pass tube modeling serpentine type evaporator, Proceedings of the ASME/JSME Thermal Engineering Conference, 2, p. 35-42.
4. Campagna, Michael 2001, An Evaporator Model which accounts for the Mal-distribution of Refrigerant applied to evaluate the Performance of Inlet Manifold Flow Distributors, Masters Thesis, Bradley University.

Single-phase flow, which is flow of fluids in a liquid phase or a vapor or gas phase, is encountered extensively in the cooling of heat generating devices such as electronics. In order to avoid unnecessary fluid flow in channels connected by manifolds, the behavior of channels and manifolds with single-phase flow needs to be understood. With proper distribution of fluid in the channels, power consumption of electronics can be maximized without shortening the life of the electronics.

### SUMMARY

An object of the present invention is to provide a heat transfer apparatus and method. Another object of the instant invention is to provide a more efficient heat transfer device and method that more properly distributes the flow of fluid. Still another object of the instant invention is to provide a method of modeling the optimization of heat transfer efficiency.

Embodiments of the present invention include a heat transfer apparatus including a manifold having an inlet and a plurality of heat exchanger channels connected to the inlet, and at least one fluid flow restrictor associated with at least one of the heat exchanger channels of the manifold. In the embodiment, the fluid flow restrictor is capable of restricting an amount of fluid flowing through the heat exchanger channel. When a fluid flow restrictor is applied to one of the heat exchanger channels, the position and extent of restriction is set in such a manner to precisely distribute the fluid flow through the manifold so as to achieve a more even temperature dissipation distribution than if no fluid flow restrictor were applied.

Embodiments of the present invention additionally include a method of improving an effectiveness of heat transfer in a heat transfer apparatus. The method includes the step of: restricting a flow of fluid to a predetermined amount in at least one manifold exchanger channel of a manifold of the heat transfer apparatus. Additionally, for each manifold exchanger channel that includes a fluid flow restrictor, the predetermined amount restricts what would otherwise be excess fluid flow through the manifold exchanger channel. As such, a force which directs more fluid to enter one manifold exchanger channel over another is countered.

Embodiments of the present invention also include a method of modeling the optimization of heat transfer effectiveness of a single-phase heat transfer apparatus, with the apparatus comprising a manifold and a plurality of manifold exchanger channels extending there through. The method includes the steps of measuring the uneven flow distribution measuring the single-phase pressure drop across manifold exchanger channels of the manifold; determining parameters for each manifold exchanger channel of the apparatus related to an uncontrolled fluid flow distribution; determining parameters for each manifold exchanger channel related to a desirable and predetermined flow distribution based on thermal needs; and determining a preferable restriction cross-sectional area of each manifold exchanger channels.

The foregoing and other objects are intended to be illustrative of the invention and are not meant in a limiting sense. The skilled artisan can readily deploy in the practice of this invention alternative methods for controlling the flow of liquid in one or more manifold exchanger channels to affect the more controlled distribution of liquid across the manifold exchanger channels of the manifold to attain more effective heat transfer of a single-phase heat transfer apparatus. Many possible embodiments of the invention may be made and will be readily evident upon a study of the following specification and accompanying drawings comprising a part thereof. Various features and sub combinations of invention may be employed without reference to other features and sub combinations. Other objects and advantages of this invention will become apparent from the following description taken in connection with the accompanying drawings, wherein is set forth by way of illustration and example, an embodiment of this invention and various features thereof.

### BRIEF DESCRIPTION OF THE DRAWINGS

A preferred embodiment of the invention, illustrative of the best mode in which the applicant has contemplated applying the principles, is set forth in the following description and is shown in the drawings and is particularly and distinctly pointed out and set forth in the appended claims.

FIG. 1 shows a front perspective schematic of a heat transfer apparatus of an exemplary embodiment of the present invention.

FIG. 2 shows a cross-section schematic view of the heat transfer apparatus of FIG. 1, taken along line 2-2 shown in FIG. 1, with the cross-section illustrating manifold exchanger channels.

FIG. 3 shows a cross-section schematic view of the heat transfer apparatus of FIGS. 1 &2 along the line B-B shown in FIG. 2, with the cross-section illustrating manifold exchanger channels.

FIG. 4 is a schematic illustration of a heat transfer rate model for an electronic component according to embodiments of the present invention.

FIG. 5 shows a flowchart for a method of determining how a flow rate of cooling fluid affects a temperature of an electronic component associated with a heat transfer apparatus.

FIGS. 6-A, 6-B, 6-C and 6-D show a flowchart for a method of predicting an effective cross-sectional restriction area of manifold exchanger channels of a heat exchanger of embodiments of the present invention.

### DETAILED DESCRIPTION

As required, several detailed embodiments of the present inventive concept are disclosed herein; however, it is to be understood that the disclosed embodiments are merely exemplary of the principles of the inventive concept, which may be embodied in various forms. Therefore, specific structural and functional details disclosed herein are not to be interpreted as limiting, but merely as a basis for the claims and as a representative basis for teaching one skilled in the art to variously employ the present inventive concept in virtually any appropriately detailed structure.

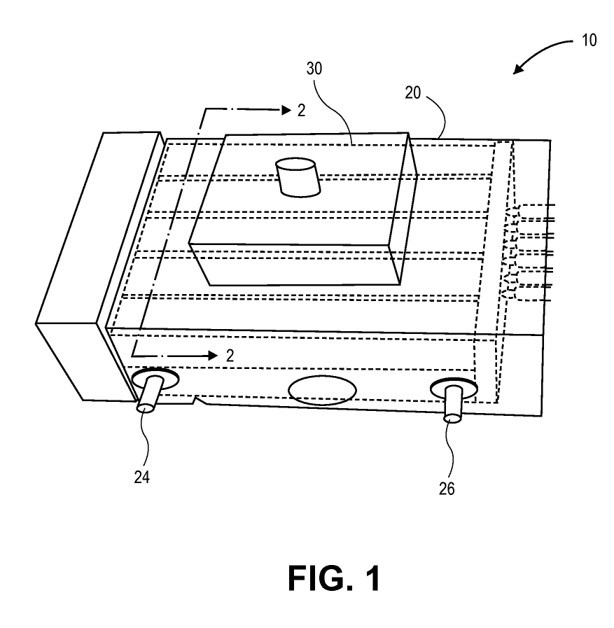

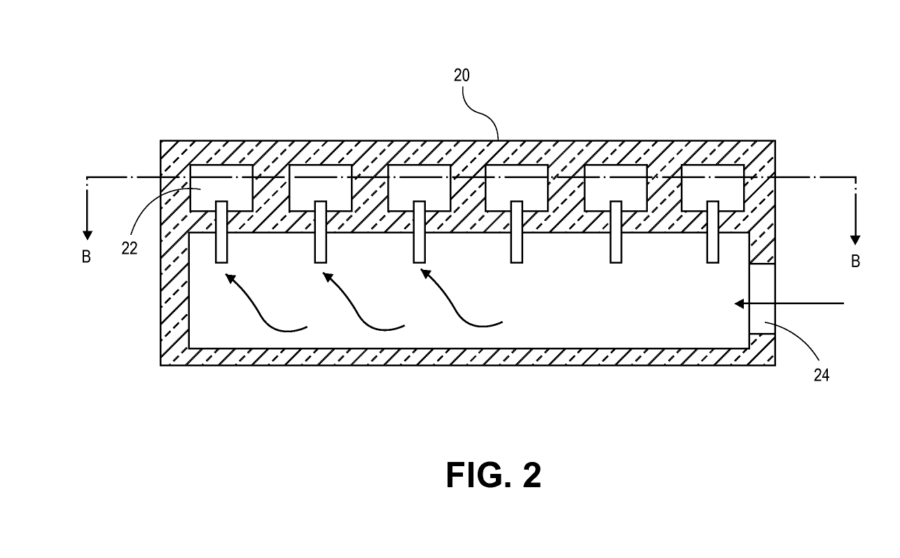

Turning to the drawings, FIGS. 1-2 illustrate schematic diagrams of a heat transfer apparatus (10) of embodiments of the present invention. The apparatus (10) of FIG. 1 includes a manifold (20) including a plurality of heat exchanger channels (22) that fluidly connect a cooling fluid inlet (24) of the manifold to a cooling fluid outlet (26) of the manifold. Fluid flows from the inlet (24), through the heat exchanger channels (22) of the manifold (20), and out the fluid outlet (26). The heat transfer device (10) additionally includes an electronic module (30) that is positioned adjacent to the manifold (20), such that heat generated by the electronic module can be dissipated via the fluid flowing through the manifold. For instance, the heat generated by the electronic module (30) may come from transistors, diodes, resistors, or other similar type electronic components included within the electronic module. In some embodiments, the apparatus (10) is used with a single-phase cooling fluid, either liquid or gas, but not both. In other embodiments, however, the apparatus is used with a two-phase cooling fluid, both liquid and gas. Thus, although the following descriptions are provided generally with respect to a single-phase cooling fluid, it is understood that embodiments of the present invention may similarly be applied to a two-phase cooling fluid.

As shown in FIG. 2, some embodiments of the present invention provide for the manifold (20) of the heat transfer apparatus (10) to include six heat exchanger channels (22) that allow cooling fluid to flow from the inlet (24) of the manifold to the outlet (26) of the manifold. However, other embodiments of the present invention contemplate that the manifold (20) will include more or less than six heat exchanger channels (22). For example, certain embodiments provide for the manifold (20) to include from one to twenty heat exchanger channels (22). In other embodiments, the manifold (20) includes more than twenty heat exchanger channels (22). Furthermore, some embodiments of the present invention provide for each of the channels (22) to include a channel inlet (32) and a channel outlet (34). The channel inlets (32) provide an entrance for fluid to flow from the inlet (24) of the manifold (20) through the channels (22). The channel outlets (34) provide an exit for fluid to flow from the channels (22) to the outlet (26) of the manifold (20).

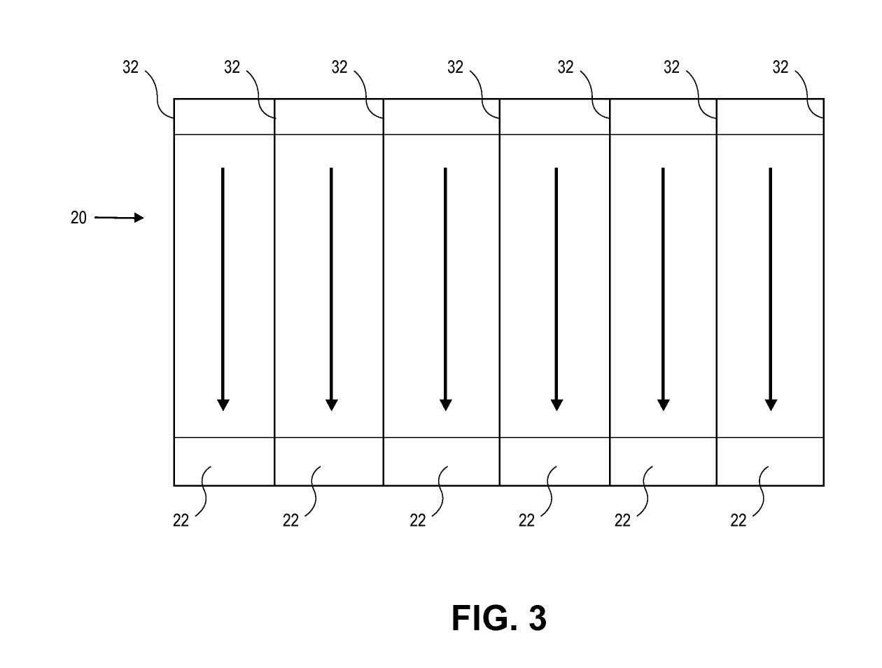

FIG. 3 illustrates a cross-sectional schematic view of the heat exchanger channels (22) of the manifold (20) from the heat transfer apparatus (10). FIG. 3 includes arrows extending along each of the heat exchanger channels (22), which indicate a direction of fluid flow through the channels. In certain embodiments, the heat exchanger channels (22) comprise straight, parallel channels, with each heat exchanger channels having sidewalls (36) that bound the channel. In certain embodiments, portions of the manifold (20), such as the heat exchanger channels (22), and the electronic module (30) are integrally formed from the same piece of material or same type of material. As such, the sidewalls (36) of the heat exchanger channels (22) are integrally formed with portions of the electronic module (30), such that heat generated by the electronic module is thermally conducted in a more efficient manner through the sidewalls of the heat exchanger channels for dissipation by the cooling fluid. In other embodiments, portions of the manifold (20) are not integrally formed with the electronic module (30), but are, instead, indirectly connected with the electronic module via an intermediate material and/or structure.

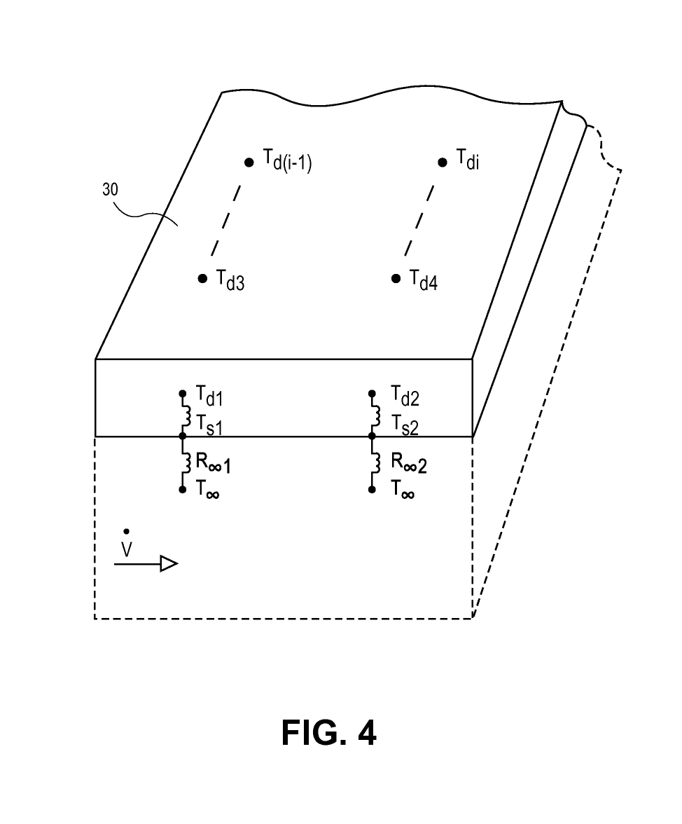

The electronic module (30) generates heat (Q) which is dissipated by the cooling fluid flowing through the manifold exchanger channels (22) of the manifold (20). As previously described, the electronic module (30) includes a plurality of electrical components. These electrical components comprise individual heat sources (e.g., junctions of transistors and/or diodes) that generate heat (Q). As seen by FIG. 4, temperatures of these heat sources of the electronic module (30) are indicated by (Tⱼ₁, Tⱼ₂, Tⱼ₃, . . . , Tⱼᵢ), where the subscript i is the number of heat sources in the electronic module. A rate of heat (\dot{Q}) dissipated from each heat source of the electronic module (30) can be modeled using a one-dimensional series of two resistances. A resistance related to a volumetric flow rate (\dot{V}) of cooling fluid is a convective resistance (R_{∞}). A driving potential (ΔT) for the rate of heat flowing through this convective resistance is a difference between a surface temperature (Tₛ) of the electronic module (30) directly underneath the heat source and a temperature of the cooling fluid (T_{∞})

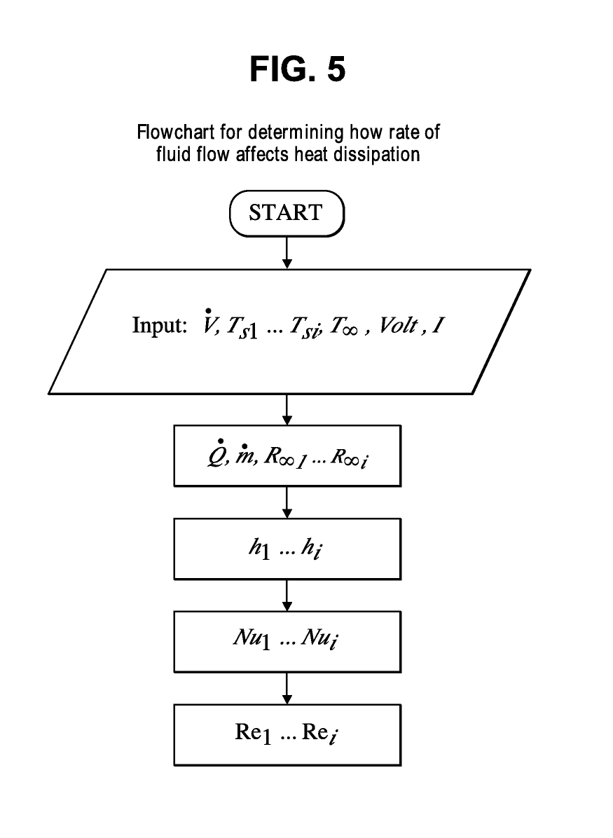

The flow rate (\dot{V}) of the cooling fluid affects an amount of heat being dissipated from the electronic module (30) and thus the temperature of the electronic module (Tⱼ). FIG. 5 is illustrates a flow chart for determining and/or illustrating how the flow rate (\dot{V}) affects heat dissipation. Beginning with the following inputs: the volumetric flow rate (\dot{V}) of coolant fluid, the surface temperatures (Tₛ₁, Tₛ₂, Tₛ₃, . . . , Tₛᵢ) of the electronic module (30) directly underneath the heat sources, and the voltage (Volt) and current (I) supplied to the electrical components defining the heat sources, it is possible to determine the rate of heat (\dot{Q}) dissipated from each heat source, the mass flow rate (\dot{m}) of the cooling fluid, and the convective resistances (R_{∞1}, R_{∞2}, R_{∞3}, . . . , R_{∞i}) for each heat source. These determinations may be quantitatively determined by implementation and analysis of the following equations:

$$\begin{matrix}\dot{Q} = ( Volt ) * ( I ) & [ 1 ] \\ \dot{m} = ρ * \dot{V} & [ 2 ] \\ ρ = f ( {T}_{∞} , {P}_{∞} ) & [ 3 ] \\ Δ {T}_{i} = {T}_{si} - {T}_{∞} & [ 4 ] \\ {R}_{∞ i} = \frac{Δ {T}_{i}}{\dot{Q}} & [ 5 ] \\ {T}_{ji} - {T}_{si} = \dot{Q} * {R}_{jc} & [ 6 ]\end{matrix}$$

As shown by Equation [1], the conservation of energy provides the rate of heat dissipated (\dot{Q}) from each heat source of the electronic module (30) is the power supplied to the electrical components of the heat source (i.e., a product of voltage (Volt) and current (I)). This equivalency assumes the parasitic heat loss from the module and its electrical connections are negligible. Next the definition of fluid density results in, Equation [2] where the mass flow rate (\dot{m}) of the cooling fluid is the product of the flow rate (\dot{V}) and the density (ρ) of the cooling fluid. Equation [3] uses a property relationship to find the density of the fluid as a function of temperature and pressure. Ohm's analogy determines Equation [4] relating the driving potential (ΔTᵢ) or the difference between the temperature (Tₛᵢ) of the bottom surface of the electronic module (30) directly underneath a heat source and the temperature (T_{∞}) of the cooling fluid to the rate of heat dissipated. Finally, Equation [5] illustrates how the convective resistances (R_{∞i}) is determined from the values determine in Equations [1] and [3]. As will be discussed below in more detail below, Equation [6] illustrates how increasing/decreasing the flow rate (\dot{V}) of the cooling fluid is used to reduce/increase the temperature (Tⱼᵢ) of the heat sources (e.g., junctions of transistors and/or diodes) within the electronics module (30).

As illustrated in FIG. 5, the next step for determining how the flow rate (\dot{V}) affects the heat dissipation is to determine the convective heat transfer coefficients (hᵢ). As shown by Equation [7] below, the convective heat transfer coefficients (hᵢ) is determined by taking the inverse of the product of the convective resistances (R_{∞i}) and the surface area (A) of a portion of the electronic component (30) directly underneath the heat source.

$${h}_{i} = \frac{1}{{R}_{∞ i} * A} \qquad [ 7 ]$$

The next step for determining how the flow rate (\dot{V}) affects the heat dissipation, as illustrated by FIG. 5, is to define the Nusselt numbers (Nuᵢ), which qualitatively, are dimensionless values representative of heat transfer coefficient in convective heat transfer. As shown by Equation [8] below, the Nusselt numbers (Nuᵢ) are defined as the product of the convective heat transfer coefficients (hᵢ) and a hydraulic diameter (Dₕ) of the manifold exchanger channel (22) divided by a thermal conductivity (k) of the cooling fluid. Alternatively, as shown by Equation [9] below, the Nusselt numbers (Nuᵢ) are empirically determined, in part, by taking the product of the Reynolds numbers (Reᵢ) and the Prandlt number (Pr). It is understood that the values (a), (m), and (n) from Equation 8 are parameters of the heat transfer apparatus (10), and may thus vary depending on specifications of the apparatus, the cooling fluid and its operating conditions.

$$\begin{matrix}{Nu}_{i} = \frac{{h}_{i} * {D}_{h}}{k} & [ 8 ] \\ {Nu}_{i} = a * {Re}_{i}^{m} * {Pr}^{n} & [ 9 ]\end{matrix}$$

As illustrated by FIG. 5, a final step for determining how the flow rate (\dot{V}) affects the heat dissipation is to define the Reynolds numbers (Reᵢ), which are used in Equation [9] to determine the Nusselt numbers (Nuᵢ). As shown in Equation [10] below, the Reynolds numbers (Reᵢ) are a product of the density (ρ) of the cooling fluid, a velocity (Vᵢ) of the cooling fluid, and the hydraulic diameter (Dₕ) of the manifold exchanger channel (22), all divided by a dynamic viscosity (μ) of the cooling fluid.

$${Re}_{i} = \frac{ρ * {V}_{i}^{*} {D}_{h}}{μ} \qquad [ 10 ]$$

Embodiments of the present invention provide for the use of Equations [1]-[10] to determine and/or illustrate how the flow rate (\dot{V}) of the cooling fluid affects the heat dissipation from and the temperature of the electronic module (30). With reference to Equation [10], as the velocities (Vᵢ) (which has a direct relationship to flow rate (\dot{V})) of the cooling fluid increases the Reynolds numbers (Reᵢ) correspondingly increase. Similarly, with reference to Equation [9], as the Reynolds numbers (Reᵢ) increase, the Nusselt numbers (Nuᵢ) will also increase. Furthermore, as illustrated by Equation [8], an increase in the Nusselt numbers (Nuᵢ) indicates a corresponding increase of the convective heat transfer coefficients (hᵢ). Because of the inverse relationship between the convective heat transfer coefficients (hᵢ) and the convective resistances (R_{∞i}), as illustrated by Equation [7], an increase in the convective heat transfer coefficients causes a reduction in the convective resistances. With reference to Equations [4] and [5], a reduction in convective resistances (R_{∞i}) indicates that the difference between temperatures of the bottom surface of the electronic module (30) and the cooling fluid (Tₛᵢ−T_{∞}) are likewise decreasing. Furthermore, with the cooling fluid held at a constant temperature (T_{∞}), the temperatures (Tₛᵢ) of the bottom surface of the electronic module (30) must also decrease with any reduction in convective resistances (R_{∞i}). Therefore, with reference to Equation [6], as the temperatures (Tₛᵢ) of the bottom surface of the electronic module (30) and the convective resistances (R_{∞i}) decrease, so will the temperatures (T_{di}) of these heat sources of the electronic module (30) for a given power input. As such, increasing or decreasing the flow rate (\dot{V}) and/or the velocity (Vᵢ) of the cooling fluid causes a corresponding decrease or increase in the temperatures (Tⱼᵢ) of the heat sources to desirable levels.

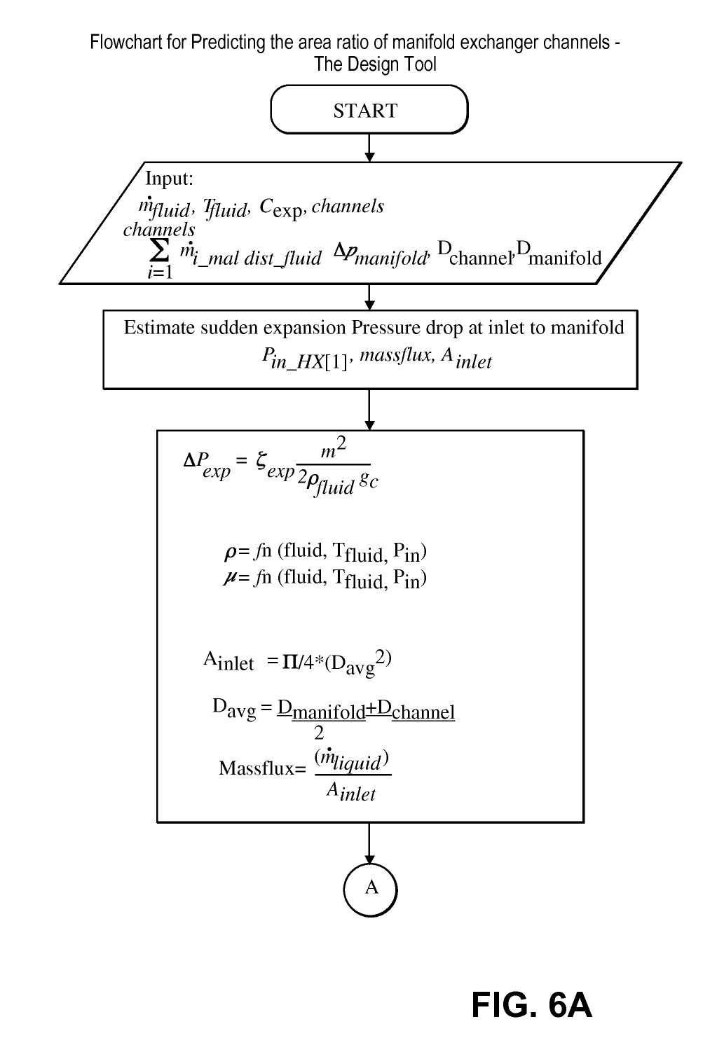

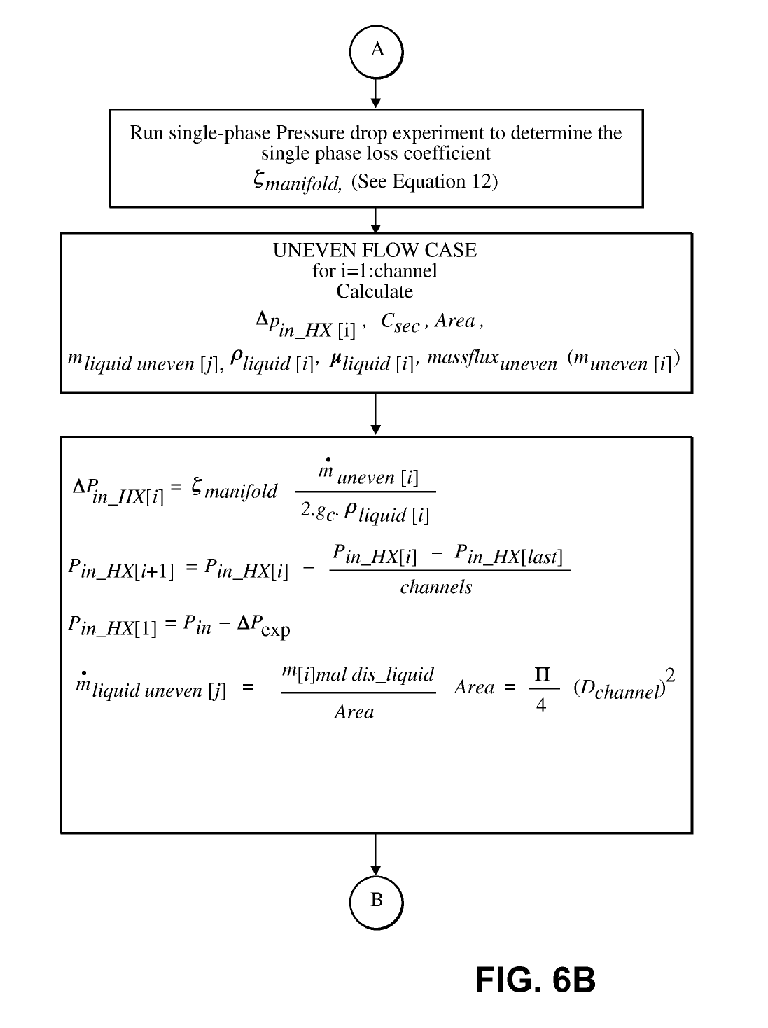

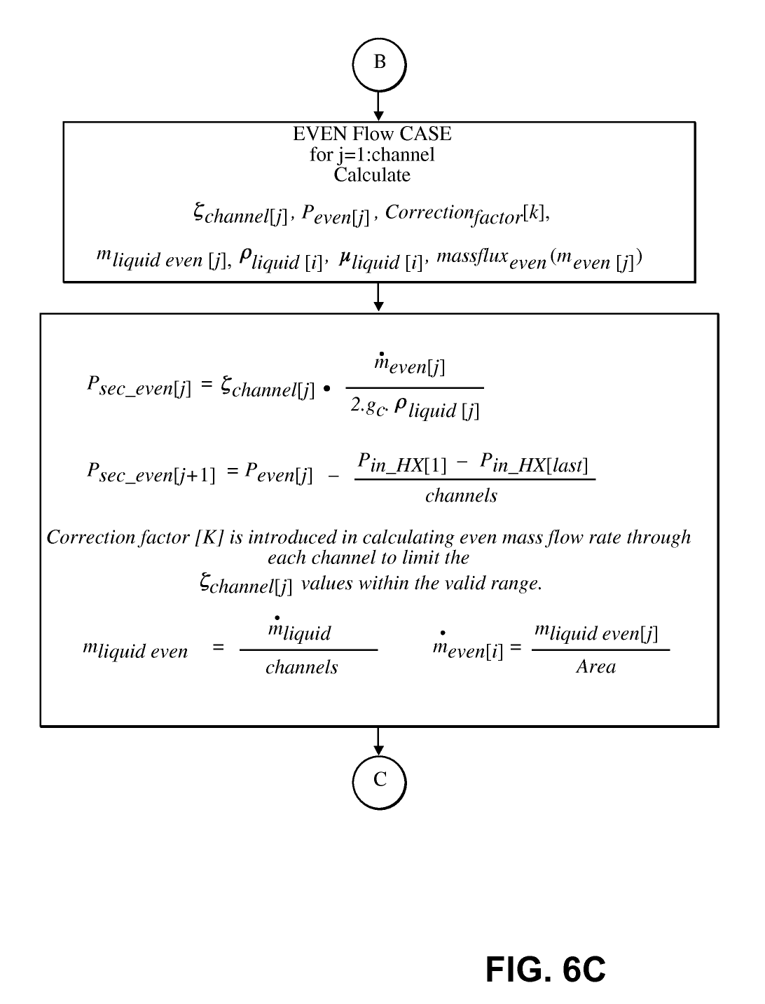

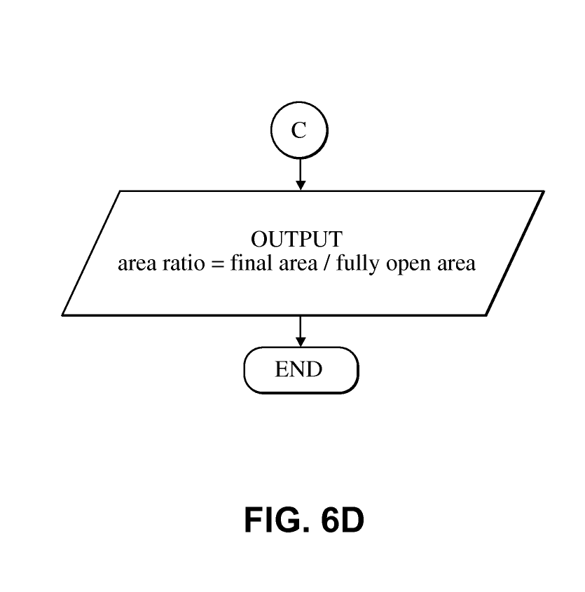

In certain embodiments of the present invention, it is desirable to maintain a uniform flow of cooling fluid through each of the manifold exchanger channels (22) so as to maintain an even and a constant temperature throughout the electronic module (30). As such, embodiments of the present invention provide for a restriction in the amount of cooling fluid flowing through one or more of the heat exchanger channels (22) so as to maintain uniform fluid flow through the manifold (20) and to allow for a uniformity of heat to be dissipated from the electronic module (30). Such restrictions may thus provide for the electronics module (30) to maintain uniform and constant temperature throughout its operation. In certain embodiments, flow distribution is measured according to standard deviation of liquid mass flow through the heat exchanger channels (22). Flow distribution is compared for heat transfer devices (10) with no fluid flow restrictors versus the same heat transfer devices with a flow restrictor on one or more of each of the manifold exchanger channels (22), with the flow restrictors set to a predetermined preferred restriction, so as to create an effective cross-sectional area within the manifold exchanger channels. In certain embodiments, a predetermined preferred restriction of effective cross-sectional area of each of the heat exchanger channels (22) is determined using an embodiment of a method of modeling the optimization of heat transfer efficiency of the single-phase heat transfer apparatus (10) of the instant invention, as is further discussed below with respect to the flow chart of FIGS. 6A-6D. The uniformity of heat dissipation of the heat transfer apparatus (10) is improved as the fluid flow is more precisely distributed through each of the heat exchanger channels (22) using one or more methods of fluid flow restriction through the channels. Further, at controlled mass flow rates in situations where the flow is more precisely distributed, the pressure drop through the manifold (20) separately is capable of being reduced.

There are many forces (inertial, gravitational, frictional, buoyancy, etc.) within conventional heat exchanger geometries which direct more liquid to enter some heat exchanger channels (22) over others. To counter act these forces, in certain embodiments, an additional flow restrictor is applied to the heat exchanger channels (22) so as to affect the flow of fluid through the channels. Rather than placing an insert directly within the manifold, as taught by Campagna (reference 4), embodiments provide for the flow through each of the manifold exchanger channels (22) to be restricted by various types of other flow restrictors, as will be discussed in more detail below. As such, fluid flow through the manifold (20) is precisely distributed among each of the manifold exchanger channels (22). Accordingly, when a fluid flow restrictor is applied to one of the heat exchanger channels (22), the position and extent of restriction is set in such a manner to precisely distribute the fluid flow through the manifold (20) so as to achieve a more even temperature dissipation distribution than if no fluid flow restrictor were applied.

Embodiments of the present invention provide for the measure of non-uniformity of the flow distribution to be quantified using statistical measures of standard deviation. A standard deviation value of zero indicates that a distribution of flow is uniform. The larger the standard deviation the greater is the mal-distribution of liquid among the manifold exchange channels. In the unrestricted case, for instance, the distribution is uncontrolled. In horizontal manifolds where the inlet is parallel with the manifold, the manifold exchanger channels (22) farthest from the inlet received high liquid flow rate. The non-uniformity of flow distribution when the manifold exchange channels (22) are unrestricted is very high.

In more detail, fluid flow is restricted within the channels by various types of flow restrictors. For example, embodiments of the present invention provide for the channel inlets (32) to each individual manifold exchanger channel (22) to be individually restricted to a predetermined size so as to allow for a predetermined flow of fluid to travel therethrough. Thus, if it is predetermined that for a given manifold (20) design that excess fluid is known to flow through a first exemplary manifold exchanger channel, then a channel inlet (32) to the first exemplary exchanger channel is reduced so as to correspondingly reduce the flow of fluid therethrough. Alternatively, if it is predetermined that for the given manifold (20) design that reduced fluid is known to flow through a second exemplary manifold exchanger channel, then a channel inlet (32) to the second exemplary exchanger channel is not be reduced so as to maximize the flow of fluid therethrough.

In certain other embodiments, cross-sectional areas of the manifold exchanger channels (22) are individually restricted to a predetermined size, thus creating an effective cross-sectional area, so as to allow for a predetermined flow of fluid to travel therethrough. A cross-sectional area for a manifold exchanger channel (22) is reduced in some embodiments, for instance, by having the sidewalls (36) of the manifold exchanger channel formed closer together. Thus, if it is predetermined that for a given manifold (20) design that excess fluid is known to flow through a first exemplary manifold exchanger channel, then a cross-sectional area to the first exemplary exchanger channel is reduced so as to correspondingly reduce the flow of fluid therethrough. Alternatively, if it is predetermined that for the given manifold design that reduced fluid is known to flow through a second exemplary manifold exchanger channel, then a cross-sectional area to the second exemplary exchanger channel is not be reduced so as to maximize the flow of fluid therethrough.

In even further embodiments, the manifold exchanger channel (22) are individually restricted via valves. Such valves include, in certain embodiments, reed valves, pinch valves, butterfly valves, needle valves, or the like. The valves may be associated with the channel inlet (32), the channel outlet (34), and/or a portion of the heat exchanger channel (22) disposed between the channel inlet and channel outlet. In an embodiment in which reed valves are used, the reed valves include bi-metallic reed valves or other material which responds to operating conditions such as temperature, pressure, flow, etc. whose operation is dependent on a temperature of the fluid flowing through the valve. Thus, for instance, if the temperature of the cooling fluid is relatively low, then a reed valve associated with a given exemplary heat exchanger channel is be more restricted, so as to permit less fluid flow to travel through the manifold exchanger channel (22). Alternatively, if the temperature of the cooling fluid is relative high, then the reed valve associated with the given exemplary manifold exchanger channel (22) is less restrictive, so as to permit more fluid flow to travel through the manifold exchanger channel. Such an embodiment may be beneficial, for instance, when the electronic module (30) generates less heat during initial stages of operation, but generates more heat during steady-state operation. Thus, during steady-state operation, as the electronic module (30) begins to warm up, the reed valves are operable to become less restrictive, thereby allowing more cooling fluid to flow through the manifold exchanger channels (22) to increase the amount of heat being dissipated from the electronic module (30).

To summarize then, embodiments of the present invention provide for a plurality of flow restrictors to be associated with the manifold exchanger channels (22), including for instance channel inlet restrictions, manifold exchanger channel cross-sectional area restrictions, and/or valve restrictions. However, regardless of the flow restrictors implemented, each of type of flow restrictor functions to reduce the fluid flow through a given manifold exchanger channel (22), such that the flow restrictor operates to provide a reduction in the effective cross-sectional area of the given manifold exchanger channel.

FIGS. 6A-6D depict a flowchart for predicting appropriate flow restrictions, as caused by the flow restrictors, to create effective cross-sectional areas of the manifold exchanger channels (22). In certain embodiments, determining the effective cross-sectional restriction areas is based on a loss coefficient of the flow restrictors and the liquid flow rate through each manifold exchanger channels (22) in the mal-distributed case. In certain embodiments, the loss coefficient is determined for a particular flow restrictor using single-phase pressure drop correlations. The conservation of momentum is applied to a flow restrictor (e.g. channel inlet restrictions, manifold exchanger channel cross-sectional area restrictions, and valve restrictions) resulting in Equation [11].

$$Δ {P}_{1 F} = ξ \frac{ρ * {V}^{2}}{2 {g}_{c}} \qquad [ 11 ]$$

Where,

ΔP_{1F} is the single-phase pressure drop (lb_{f}/ft²)

ξ is the single-phase loss coefficient (−)

ρ is the density of the single phase fluid (lbₘ/ft²)

V is the velocity of flow (ft/s)

g_{c} is the constant of proportionality for Newton's 2^{nd} Law (32.2 lbₘ-ft/lb_{f}-s²).

In this example, the loss coefficient is valid whether the fluid flow was liquid or gas. The single-phase pressure drop is alternatively determined using single phase loss coefficient using the relationship based on mass flux rather than velocity.

$$Δ {P}_{1 F} = ξ \frac{{\dot{m}}^{2}}{2 ρ {g}_{c}} \qquad [ 12 ]$$

Where,

\dot{m} is the mass flux (lbₘ/ft²).

The input variables are mass flow rates of cooling fluid (\dot{m}), pressure at the inlet (24) to the manifold Pᵢₙ, pressure drop across the manifold ΔP_{manifold}, temperatures of fluid at the inlet of manifold, number of manifold exchanger channels (22), liquid flow rates through the manifold exchanger channels without restriction

$${\sum }_{i = 1}^{channels} {\dot{m}}_{i\_mal dist\_cooling \_fluid} ,$$

diameter of the manifold exchanger channels (22) and diameter of the inlet to the manifold, and the single-phase loss coefficient for the sudden expansion at the inlet.

The first step in the model is to estimate a sudden expansion single-phase pressure drop at the inlet (24) of the manifold. The single-phase pressure drop at the inlet (24) is determined based on the inlet diameter of the pipe and the hydraulic diameter of the manifold, the mass flux, and density of the fluid. In certain embodiments, the single-phase loss coefficient ξₑₓₚ, is obtained from a table of values, such as given by Paliwoda (reference 2), and is based on the square of the ratio of diameters, (d/D)² where, d, is the inlet (24) pipe diameter and D is the hydraulic diameter of the manifold (20). The pressure at the outlet of each heat exchanger channel (22) is a difference of the pressure at the inlet (24), the pressure loss in the manifold, the single-phase pressure drop at the contraction through the heat exchanger channel and the pressure loss along the heat exchanger channel.

The second step is to predict the single-phase pressure drop in the manifold. This is determined by single-phase pressure drop correlation with a manifold loss coefficient using Equation [12]. In certain embodiments, the single-phase loss coefficient across the manifold is determined experimentally by measuring the pressure drop across the manifold using a constant known liquid flow rate and manometers connected to static pressure rings to measure pressures along the manifold.

The third step is to determine the parameters for each manifold exchanger channel (22) of the manifold (20) related to uncontrolled flow distribution. In certain embodiments, pressure at the inlet to each of the manifold exchanger channels (22) is determined using Equations [14] and [15]. Then, embodiments provide for this pressure drop to be used with Equation [13] to determine the single-phase loss coefficient.

$$\begin{matrix}{\sum }_{i = 1}^{last} {P}_{in\_HX [ i ]} = {ξ}_{manifold} \cdot \frac{{m}_{uneven [ i ]}^{2}}{2 {g}_{c} {ρ}_{fluid}} & [ 13 ] \\ {\sum }_{i = 1}^{last - 1} {P}_{in\_HX [ i + 1 ]} = {P}_{in\_HX [ i ]} - \frac{{P}_{in\_HX [ 1 ]} - {P}_{in\_HX [ last ]}}{channels} & [ 14 ] \\ {P}_{in\_HX [ 1 ]} = {P}_{in} - Δ {P}_{exp} & [ 15 ]\end{matrix}$$

The mass flux is based on the mass of the fluid of the single-phase flow at each manifold exchanger channel (22). The area considered to calculate the mass flux is the cross-sectional area the manifold (24).

The fourth step is to repeat step three and evaluate the controlled flow distribution parameters. Using the single-phase loss coefficient, C_{sec}, this is a result from step three, ξ_{channel} the single-phase loss coefficient for each manifold exchanger channel (22) which is a function of restriction that causes controlled flow for each channel is determined. On the other hand, using Equation [11], embodiments provide for ξ_{channel} to be experimentally determined using a single manifold exchanger channel (22) by varying restriction via the flow restrictor. Results showed that the single-phase loss coefficient may same for the fluid whether it is gas or liquid.

In embodiments in which valves are used as flow restrictors, an empirical correlation for valve position as a function of ξ_{channel} is measured. Such correlations are determined based on fitting data with polynomial equations in piece-wise manners. In certain embodiments, a correction factor [K] may be introduced in calculating controlled mass flow rate through each manifold exchanger channel (22) to limit the ξ_{channel[j]} values within a valid range for the valve.

The fifth step is to calibrate the fluid flow restrictor. In certain embodiments, the fluid flow restrictors are associated with graduations that indicate an effective cross-sectional area of the manifold exchanger channels (22). The graduations are not necessarily required to have any dimensional significance other than fully open, fully closed, and/or one or more intermediate graduation levels. In certain embodiments, experimentation is required to correlate the graduations to the restriction of effective cross-sectional area. In some embodiments, such experimentation quantitatively uses polynomial correlations to estimate relationships between graduation and effective cross-sectional area after restriction. Multiple experimental data sets may be used to reduce and/or minimize the error.

The sixth step is to determine any required zero offset values in order to limit the flow restrictor settings, as may be required. In certain embodiments, the zero offsets is iteratively determined and used as multiples as constant term within calculations used to determine the effective cross-sectional area equation.

The seventh step is to determine a preferable restriction in effective cross-sectional area of each flow restrictor. A cross-sectional area ratio of each manifold exchanger channel (22) is specified such that the fluid in the manifold at a specified operating condition is more precisely distributed. The area ratio is equal to the final area/fully open area. The final area is the cross-sectional area of the realized manifold exchanger channel (22) after restriction and the fully open area is the manifold exchanger channel cross-sectional area at no restriction. Thus, an area ratio equal to one is fully open and zero is fully closed.

In certain embodiments with multiple heat exchanger channels (22), it is preferred to allow fluid to flow unrestricted through at least one of the channels (22) of the manifold (20), while others of the channels (22) have a restricted fluid flow. In such embodiments, the fluid flows unrestricted through the unrestricted channel (22) because the channel does not have a fluid flow restrictor associated with it. For instance, in some embodiments, a heat exchanger channel (22) positioned near and/or otherwise associated with electrical component(s) of the electronic module 30 that generate a higher temperature than surrounding component(s) (e.g., transistors) will have fluid flowing therethrough unrestricted and thus have a greater fluid flow than if a flow restrictor was present. In some embodiments, the fluid flowing through the remaining channels (22) will be restricted, as previously described, via the fluid flow restrictors.

Although some embodiments of the present invention are directed to providing a uniform rate of flow of fluid through each of the heat exchanger channels (22) of the manifold (20), other embodiments of the present invention provide for one or more of the channels to have different rates of fluid flow (by volume) with respect to fluid flow rate of other channels. The different rates of fluid flow through the heat exchanger channels (22) are created via the use of the flow restrictors, as previously described. In such embodiments, the flow of fluid is increased to channels (22) positioned near and/or otherwise associated with electrical components that generate more heat. Similarly, the flow of fluid may be decreased to channels (22) positioned near and/or otherwise associated with electrical components that generate less heat. Thus, in some embodiments, the fluid flow to each of the channels (22) in the manifold is established individually and is unrelated to the fluid flow rate of the other channels (22). As such, the electronic module 30 is maintained within a desirable temperature range.

In additional embodiments, the electronic module (30) is designed with the electrical components having a higher temperature (e.g., transistors) being positioned near and/or otherwise associated with a channel (22) having a higher rate of heat transfer (i.e., by for example, having a higher volumetric flow rate of cooling fluid). Alternatively, in some embodiments, the manifold (20) is designed such that a channel (22) with a higher rate of heat transfer is positioned near and/or otherwise associated with an electrical component that generates more heat. In additional embodiments, the electronic module (30) is designed with the electrical components that generate more heat (e.g., transistors) being positioned closer to a channel inlet (32) of a channel (22). Because the fluid flowing through the channel (22) will absorb heat from the electronics module (30) as the fluid passes through the channel, the fluid near the channel inlet (32) of the channel will generally have a lower temperature than the fluid near the channel outlet (34) of the channel. Thus, designing the electronics module 30 such that the electrical components that generate the most heat are positioned near the channel inlets (32) will allow the manifold (20) to better dissipate heat from the electronics module (30). Alternatively, instead manifold 20 is designed such that the inlets to the channels 22 are positioned near the electrical components that generate more heat. In the foregoing description, certain terms have been used for brevity, clearness and understanding; but no unnecessary limitations are to be implied therefrom beyond the requirements of the prior art, because such terms are used for descriptive purposes and are intended to be broadly construed. Moreover, the description and illustration of the inventions is by way of example, and the scope of the inventions is not limited to the exact details shown or described.

Although the foregoing detailed description of the present invention has been described by reference to an exemplary embodiment, and the best mode contemplated for carrying out the present invention has been shown and described, it will be understood that certain changes, modification or variations may be made in embodying the above invention, and in the construction thereof, other than those specifically set forth herein, may be achieved by those skilled in the art without departing from the spirit and scope of the invention, and that such changes, modification or variations are to be considered as being within the overall scope of the present invention. Therefore, it is contemplated to cover the present invention and any and all changes, modifications, variations, or equivalents that fall with in the true spirit and scope of the underlying principles disclosed and claimed herein. Consequently, the scope of the present invention is intended to be limited only by the attached claims, all matter contained in the above description and shown in the accompanying drawings shall be interpreted as illustrative and not in a limiting sense.

Having now described the features, discoveries and principles of the invention, the manner in which the invention is constructed and used, the characteristics of the construction, and advantageous, new and useful results obtained; the new and useful structures, devices, elements, arrangements, parts and combinations, are set forth in the appended claims.

It is also to be understood that the following claims are intended to cover all of the generic and specific features of the invention herein described, and all statements of the scope of the invention which, as a matter of language, might be said to fall therebetween.

What is claimed is:

1. A heat transfer apparatus comprising:
a manifold having an inlet and a plurality of heat exchanger channels connected to the inlet, and
at least one fluid flow restrictor associated with at least one of the heat exchanger channels of the manifold, wherein the fluid flow restrictor is operable to restrict an amount of fluid flowing through the heat exchanger channel.

2. The apparatus of claim 1, wherein each of the plurality of heat exchanger channels includes a fluid flow restrictor.

3. The apparatus of claim 2, wherein at least one of said fluid flow restrictors comprises an inlet restriction.

4. The apparatus of claim 1, wherein at least one of the plurality of heat exchanger channels does not include a fluid flow restrictor.

5. The apparatus of claim 4, wherein at least one of said fluid flow restrictors comprises an inlet restriction.

6. The apparatus of claim 1, wherein the fluid flow restrictor is selected from the group consisting of a channel inlet restriction, a manifold exchanger channel size restriction, and a valve restriction.

7. The apparatus of claim 1, wherein the fluid flow restrictor is a bi-metallic reed valve.

8. The apparatus of claim 1, wherein the fluid flow restrictor is a material which responds to one or more operating condition.

9. The apparatus of claim 8, wherein said one or more operating conditions include at least one of temperature, pressure, or flow.

10. The apparatus of claim 1, wherein the fluid flow restrictor is operable to provide a variable restriction in response to a change in one or more operating conditions.

11. The apparatus of claim 1, further comprising:
wherein the heat transfer apparatus is configured to dissipate heat from an electronic component,
wherein each of the manifold exchanger channels include sidewalls, and further wherein a portion of the sidewalls are integrally formed with at least a portion of the electronic component, so as to thermally conduct heat away from the electronic component.

12. The apparatus of claim 1, wherein the fluid is liquid.

13. The apparatus of claim 1, wherein the fluid is vapor.

14. The apparatus of claim 1, wherein the fluid comprises both liquid and vapor.

15. The apparatus of claim 1, wherein the fluid is a refrigerant.

16. A method of improving an efficiency of heat transfer in a heat transfer apparatus, the method comprising the steps of:
restricting a flow of fluid to a predetermined amount in at least one manifold exchanger channel of a manifold of the heat transfer apparatus;
wherein in each manifold exchanger channel that includes a fluid flow restrictor, the predetermined amount is operable to restrict what would otherwise be excess fluid flow through the manifold exchanger channel, whereby a force which directs more fluid to enter one manifold exchanger channel over another is countered.

17. The method of claim 16, wherein the heat transfer apparatus is operable to dissipate heat from an electronics module, the method further comprising:
increasing a volumetric flow of fluid in a manifold exchanger channel associated with a first portion of the electronics module that generates more heat than a second portion of the electronics module.

18. The method of claim 16, wherein the heat transfer apparatus is operable to dissipate heat from an electronics module, the method further comprising:
reducing a volumetric flow of fluid in a manifold exchanger channel associated with a first portion of the electronics module that generates less heat than a second portion of the electronics module.

19. The method of claim 16, wherein each of the manifold exchanger channels includes a fluid flow restrictor.

20. The method of claim 16, wherein at least one of the fluid flow restrictors comprises an inlet restriction.

21. The method of claim 16, wherein at least one of the heat exchanger channels of the manifold does not include a fluid flow restrictor.

22. The method of claim 16, wherein the fluid flow restrictor is selected from the group consisting of a channel inlet restriction, a manifold exchanger channel size restriction, and a valve restriction.

23. The method of claim 16, wherein the fluid flow restrictor is a bi-metallic reed valve.

24. The method of claim 16, wherein the fluid flow restrictor is a material which responds to one or more operating conditions.

25. The method of claim 24, wherein the one or more operating conditions include at least one of temperature, pressure, or flow.

26. The method of claim 16, wherein the fluid flow restrictor is operable to provide a variable restriction in response to a change in one or more operating conditions.

27. The method of claim 16, wherein the heat transfer apparatus is configured to dissipate heat from an electronic component,
wherein each of the manifold exchanger channels include sidewalls, and further wherein a portion of the sidewalls are integrally formed with at least a portion of the electronic component, so as to thermally conduct heat away from the electronic component.

28. The method of claim 16, wherein the fluid is liquid.

29. The method of claim 16, wherein the fluid is vapor.

30. The method of claim 16, wherein the fluid comprises both liquid and vapor.

31. A method of modeling the optimization of heat transfer efficiency of a single-phase heat transfer apparatus, the apparatus comprising a manifold with a plurality of manifold exchanger channels extending therethrough, the method comprising the steps of:
estimating sudden expansion single-phase pressure drop at an inlet of the manifold;
predicting the single-phase pressure drop across the manifold;
determining parameters for each manifold exchanger channel of the apparatus related to an uncontrolled fluid flow distribution;
determining parameters for each manifold exchanger channel related to an controlled flow distribution; and
determining a preferable restriction cross-sectional area of each manifold exchanger channel.

32. The method of claim 31, wherein the apparatus further comprises a fluid flow restrictor associated with at least one of the plurality of heat exchanger channels, the method further comprising the steps of:
determining flow rates through the apparatus without restriction; and
calibrating a dimensionless position of each fluid flow restrictor to a restriction cross-sectional area of each respective heat exchanger channels.

33. The method of claim 31, further comprising the step of: restricting the cross-sectional area of at least one heat exchanger channel to the preferable restriction cross-sectional area.

34. A system for heat transfer, the system comprising:
an electronics module with a plurality of electronics components that generate heat; and
a heat exchanger apparatus for dissipating the heat generated by the electronics components of the electronics module, wherein the heat exchanger includes a manifold having a plurality of heat exchanger channels with a cooling fluid flowing therethrough,
wherein an electrical component that generates more heat than an other electrical components is associated with a portion of the heat exchanger channels that removes more heat than an other portion of the heat exchanger channels.

35. The system of claim 34, wherein the electrical components are positioned within the electronics module such that said electrical component that generates more heat is associated with said portion of the heat exchanger channels that removes more heat.

36. The system of claim 34, wherein the heat exchanger channels are positioned within the manifold such that said electrical component that generates more heat is associated with said portion of the heat exchanger channels that removes more heat.
